(19) United States
(12) Patent Application Publication
(10) Pub. No.: US 2014/0166840 A1
(43) Pub. Date: Jun. 19, 2014

(54) Substrate Carrier

(71) Applicant: INTERMOLECULAR, INC., San Jose, CA (US)

(72) Inventors: Wayne R. French, San Jose, CA (US); Kent Riley Child, Dublin, CA (US); Alonzo T. Collins, Fremont, CA (US); Jay B. Dedontney, Prunedale, CA (US); Richard R. Endo, San Carlos, CA (US); Aaron T. Francis, San Jose, CA (US); Zachary Fresco, Redwood City, CA (US); Edward L. Haywood, San Jose, CA (US); Ashley David Lacey, Dublin, CA (US); Monica Sawkar Mathur, San Jose, CA (US); James Tsung, Milpitas, CA (US); Danny Wang, Saratoga, CA (US); Kenneth A. Williams, Livermore, CA (US); Maosheng Zhao, San Jose, CA (US)

(73) Assignee: INTERMOLECULAR, INC., San Jose, CA (US)

(21) Appl. No.: 13/716,044

(22) Filed: Dec. 14, 2012

(51) Int. Cl. H01L 21/687

(52) U.S. Cl. CPC H01L 21/68728
USPC 248/346.04; 248/346.03

(57) ABSTRACT

A substrate carrier is provided. The substrate carrier includes a base for supporting a substrate. A plurality of support tabs is affixed to a surface of the base. The plurality of support tabs have a cavity defined within an inner region of each support tab of the plurality of support tabs. A plurality of protrusions extends from the surface of the base, wherein one of the plurality of protrusions mates with one cavity to support one of the plurality of support tabs. A film is deposited over the surface of the base, surfaces of the plurality of support tabs and surfaces of the plurality of protrusions.

### BACKGROUND

Combinatorial processing enables rapid evaluation of semiconductor processes. The systems supporting the combinatorial processing are flexible to accommodate the demands for running the different processes either in parallel, serial or some combination of the two.

Some exemplary semiconductor wet processing operations include operations for adding (electro-depositions) and removing layers (etch), defining features, preparing layers (e.g., cleans), etc. Similar processing techniques apply to the manufacture of integrated circuits (IC) semiconductor devices, flat panel displays, optoelectronics devices, data storage devices, magneto electronic devices, magneto optic devices, packaged devices, and the like. As feature sizes continue to shrink, improvements, whether in materials, unit processes, or process sequences, are continually being sought for the deposition processes. However, semiconductor companies conduct R&D on full wafer processing through the use of split lots, as the deposition systems are designed to support this processing scheme. This approach has resulted in ever escalating R&D costs and the inability to conduct extensive experimentation in a timely and cost effective manner. Combinatorial processing as applied to semiconductor manufacturing operations enables multiple experiments to be performed on a single substrate.

During combinatorial experiments it is beneficial to provide as much flexibility as possible with regard to the tools performing the processing. In addition, the equipment for performing the combinatorial experiments should be designed to accommodate different size substrates and coupons for the combinatorial processing. It is within this context that the embodiments arise.

### SUMMARY

Embodiments of the present invention provide a substrate carrier that is capable of accommodating different size substrates and coupons for combinatorial processing. Several inventive embodiments of the present invention are described below.

In some embodiments of the invention a substrate carrier is provided. The substrate carrier includes a base for supporting a substrate. A plurality of support tabs are affixed to a surface of the base. The plurality of support tabs have a cavity defined within an inner region of each support tab of the plurality of support tabs. A plurality of protrusions extend from the surface of the base, wherein one of the plurality of protrusions mates with one cavity to support one of the plurality of support tabs. A film is deposited over the surface of the base, surfaces of the plurality of support tabs and surfaces of the plurality of protrusions.

Other aspects of the invention will become apparent from the following detailed description, taken in conjunction with the accompanying drawings, illustrating by way of example, the principles of the invention.

### BRIEF DESCRIPTION OF THE DRAWINGS

The present invention will be readily understood by the following detailed description in conjunction with the accompanying drawings, and like reference numerals designate like structural elements.

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration that includes site isolated processing and/or conventional processing in accordance with some embodiments of the invention.

FIG. 3 is a simplified schematic diagram illustrating of a substrate carrier in accordance with some embodiments.

FIG. 4 is a simplified schematic diagram of the mating component for a notch of a substrate supported by the substrate carrier in accordance with some embodiments.

FIG. 5 is a simplified schematic diagram illustrating an alternative embodiment for substrate carrier in accordance with some embodiments.

FIG. 6 is a simplified schematic diagram illustrating a substrate carrier configured to support ten coupons in accordance with some embodiments.

FIG. 7 is a simplified schematic diagram illustrating a substrate carrier having a plurality of support tabs configured to support coupons or substrates in accordance with some embodiments.

FIG. 8 is a simplified schematic diagram illustrating the components of a support tab and an anchoring mechanism for the support tab in accordance with some embodiments.

### DETAILED DESCRIPTION

The embodiments described herein provide a method and apparatus for a versatile substrate carrier that can accommodate various size substrates for combinatorial processing. It will be obvious, however, to one skilled in the art, that the present invention may be practiced without some or all of these specific details. In other instances, well known process operations have not been described in detail in order not to unnecessarily obscure the present invention.

The embodiments described below provide a carrier so that deposition tools built for 300 millimeter (mm) wafers are able to process wafers and coupons that are smaller than 300 mm. Thus, the combinatorial experiments may be on multiple substrate sizes within equipment originally designed for a single substrate size. The substrate carriers are capable of providing accurate placement of the substrates so that multiple depositions may be performed through site isolation. In some embodiments, different types of substrates may be placed on the substrate carrier for combinatorial processing operations. In some embodiments, the same type of substrate may be placed on the substrate carrier for the combinatorial processing.

Semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, e.g., different substrates and chemical reactants, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning HPC processing techniques have also been successfully adapted to deposition processes such as physical vapor deposition (PVD), atomic layer deposition (ALD), and chemical vapor deposition (CVD).

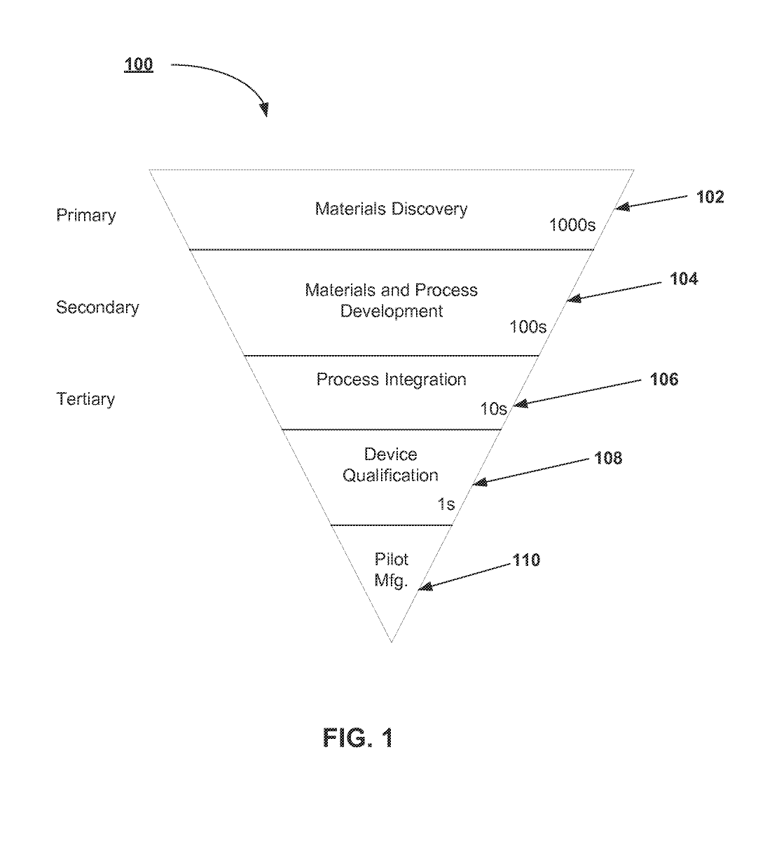

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

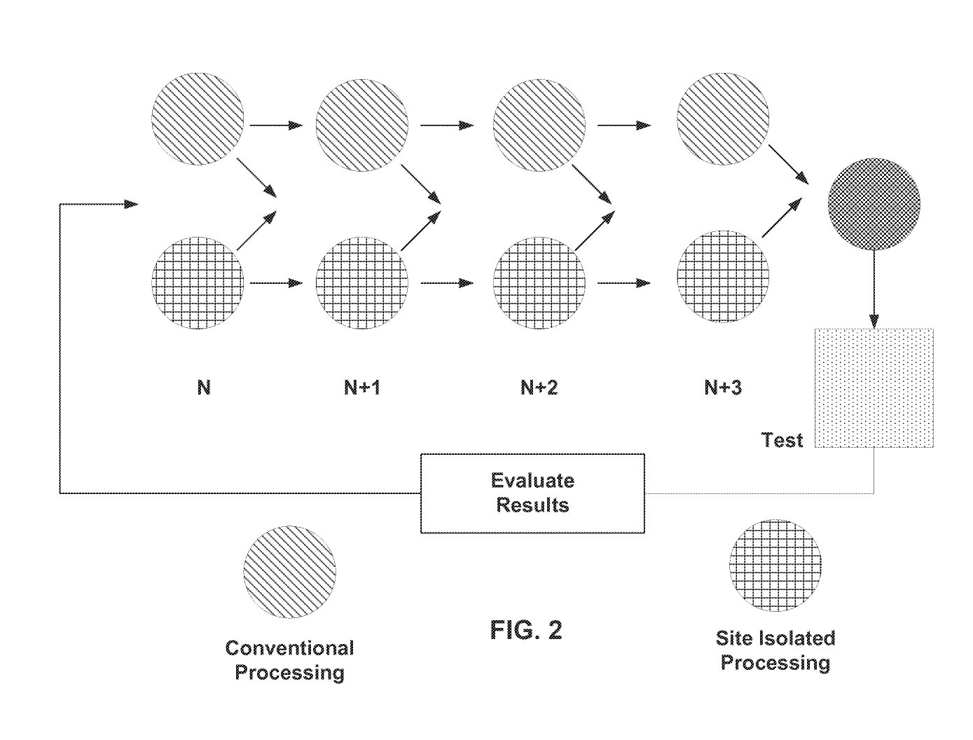

FIG. 2 is a simplified schematic diagram illustrating a general methodology for combinatorial process sequence integration that includes site isolated processing and/or conventional processing in accordance with some embodiments of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

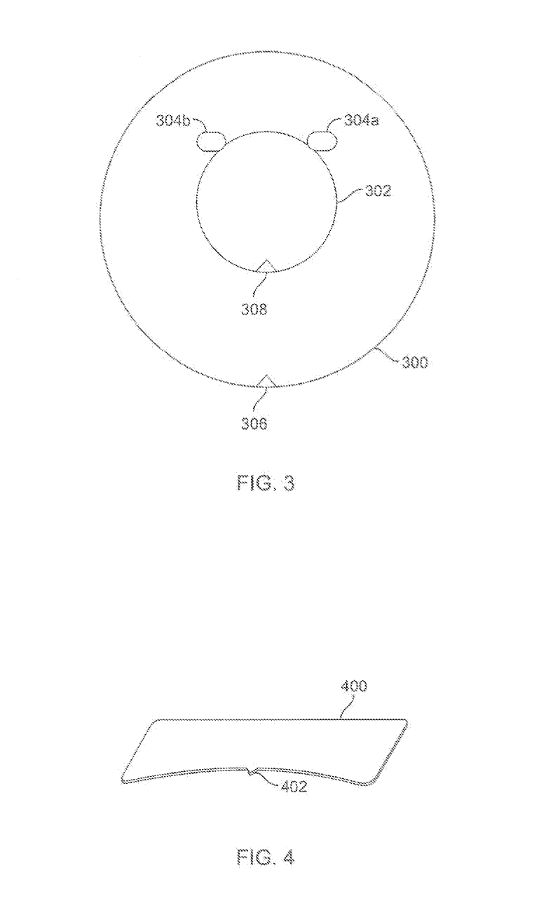

FIG. 3 is a simplified schematic diagram illustrating of a substrate carrier in accordance with some embodiments. Substrate carrier 300 is configured to support substrate 302. Support tabs 304A and 304B, along with a support configured to mate with notch 308, such as the support illustrated with regard to FIG. 4, secure substrate 302 for processing. Notch 306 of substrate carrier 300 and notch 308 of substrate 302 are aligned with each other in some embodiments. Therefore, in the case where substrate carrier 300 is a substrate carrier of one size, e.g., a 300 mm substrate carrier, and substrate 302 is a 200 mm substrate, the alignment of substrate carrier 300 will translate to the alignment of substrate 302 through correlated notches 306 and 308. Support tabs 304A and 304B are fixed to a surface of substrate carrier 300. Alternative types of affixing can include, screwing, pins extending from and/or through the surface of the substrate carrier. In addition, the shapes and position of the support tabs are not limited by the illustrated shapes and positions, as any suitable shape and/or position may be utilized for the support tabs. In some embodiments support tabs 304A and 304B are glued or adhered to a surface of substrate carrier 300. Substrate carrier 300 may be composed of silicon or silicon oxide in some embodiments. In some embodiments, substrate carrier 300 may be composed of silicon or silicon oxide and support tabs 304A and 304B, along with the mating component for notch 308. A thin film may be deposited over an entirety of the surface of substrate carrier 300. The thin film encapsulates or blankets the surface of the substrate carrier, the substrate or coupons, and any support tabs.

FIG. 4 is a simplified schematic diagram of the mating component for a notch of a substrate supported by the substrate carrier in accordance with some embodiments. Mating component 400 may be affixed to a surface of the substrate carrier such that the notch protrusion 402 mates with a notch of the substrate that is supported by the substrate carrier. Notch protrusion 402 may be aligned with another alignment marker of the substrate carrier associated with the notch for a different size substrate.

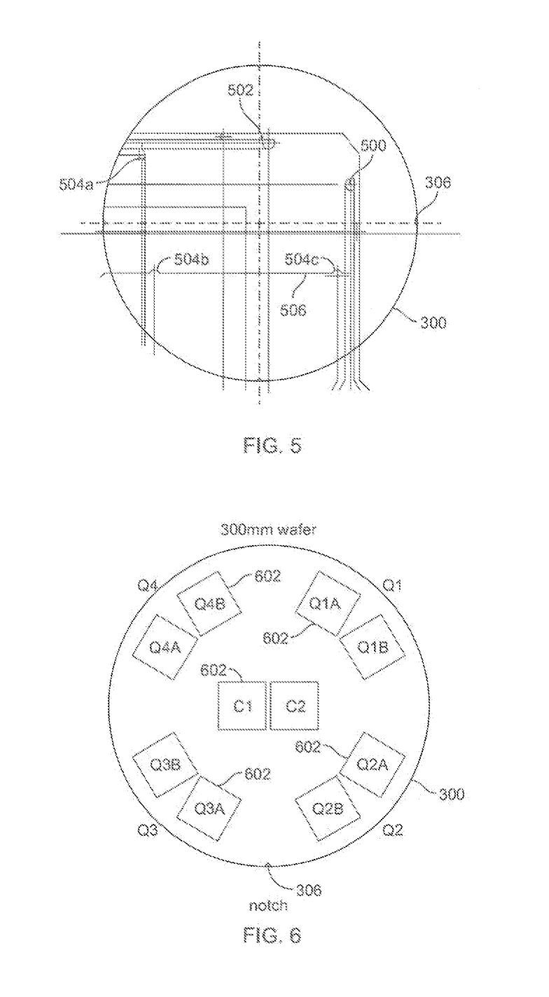

FIG. 5 is a simplified schematic diagram illustrating an alternative embodiment for substrate carrier in accordance with some embodiments. Substrate carrier 300 having notch 306 defined thereon is configured to support coupon 506. In some embodiments coupon 506 may be rectangular or square shaped as opposed to a circular substrate. Support tabs 500 and 502 are configured to provide pressure against a side surface of a coupon supported between the surfaces of support tabs 500 and 502, as well as supports 504A through 504C. It should be appreciated that supports 504A through 504C may be extensions deposited on a surface of substrate carrier 300 or pins extending from the surface of the substrate carrier. In some embodiments support tabs 500 and 502 are spring-loaded so that the support tabs 500 and 502 supply a force or maintain a tension against the peripheral edges of a coupon contacting a surface of the support tabs to force the substrates against supports 504A-C.

FIG. 6 is a simplified schematic diagram illustrating a substrate carrier configured to support ten coupons in accordance with some embodiments. Substrate carrier 300 has notch 306 disposed on an outer peripheral surface. Coupons 602 are supported on a surface of substrate carrier 300. It should be appreciated that coupons 602 are supported in each quadrant of substrate carrier 300 with an additional two coupons 602 supported in a center region of substrate carrier 300. As illustrated in FIG. 6, coupons 602 are a square shape while substrate carrier 300 is circular. However, any combination of geometric shapes may be used for the coupons 602 and the carrier 300. Coupons 602 may be supported by extensions extending from a surface of substrate carrier 300. In some embodiments the extensions supporting coupons 602 may be affixed or adhered to the surface, deposited onto the surface, or extend through the surface of substrate carrier 300. The shape of the extensions may be any suitable geometric shape in some embodiments. As mentioned above, a surface of substrate carrier 300 with the extensions disposed thereon may have a thin film deposited over the entirety of the surface of substrate 300 so that any adherent or material utilized for securing the extensions that may have a different composition from the substrate carrier and the extensions is not exposed to a processing environment.

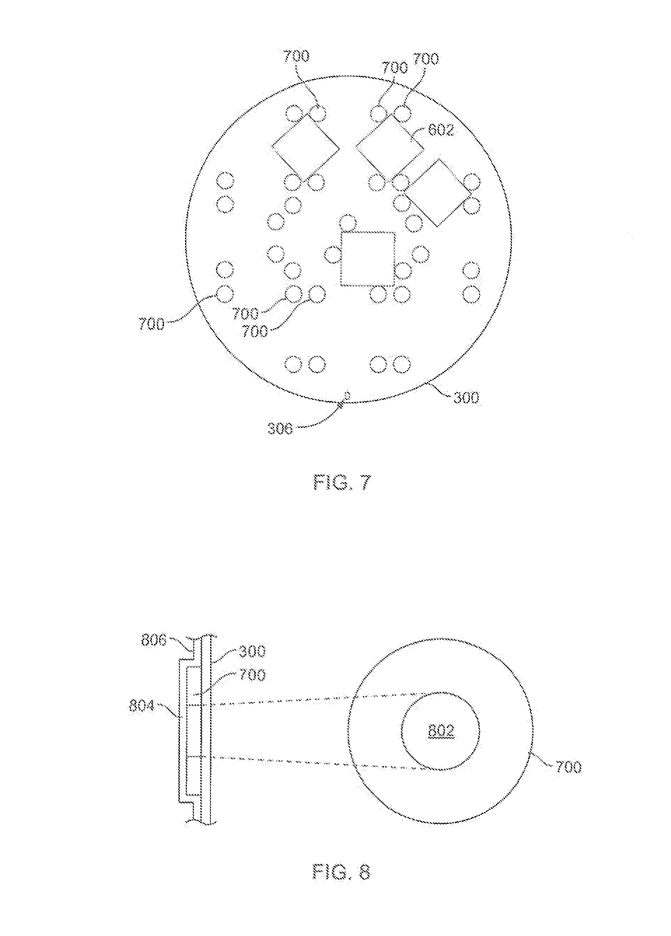

FIG. 7 is a simplified schematic diagram illustrating a substrate carrier having a plurality of support tabs configured to support coupons or substrates in accordance with some embodiments. Support tabs 700 are disposed over a surface of substrate carrier 300. In the example embodiment of FIG. 7 support tabs 700 are circular and coupons 602 are square. In this embodiment four support tabs 700 support one coupon 602. Alignment notch 306 is configured to provide a reference for aligning substrate carrier 300 in some embodiments. Support tabs 700 provide pockets to place coupons 602 at various positions on the surface of the substrate carrier 300. In some embodiments, different size coupons may be placed over the surface of substrate carrier 300. The location and configuration of support tabs 700 is not limited to the example illustrated in FIG. 7 as any location or combination of locations may be integrated into the embodiments.

FIG. 8 is a simplified schematic diagram illustrating the components of a support tab and an anchoring mechanism for the support tab in accordance with some embodiments. Support tabs 700 are illustrated as a ring having a cavity 802 defined within a center region of the ring. Cavity 802 mates with protrusion 804, which extends from a surface of substrate carrier 300. In some embodiments protrusion 804 is composed of an epoxy material and may be referred to as an epoxy pillar or extension. Support tab 700 is composed of a silicon material identical to the composition of substrate carrier 300 in some embodiments. Materials other than silicon, such as ceramic and quartz, may be utilized in other embodiments. In the cross sectional view portion of FIG. 8, thin film 806 is deposited over a surface of each of substrate carrier 300, support tab 700, and protrusion 804. It should be appreciated that thin film 806 may be deposited through any known deposition technique, such as physical vapor deposition, chemical vapor deposition, atomic layer deposition, etc. In some embodiments, thin film 806 is composed of silicon dioxide. It should be appreciated that thin film 806 encapsulates the entirety of substrate carrier 300 and the surface components to prevent exposure of the material composing protrusion 804 during a processing operation. It should be further appreciated that the pillar configuration of protrusion 904 accommodates the thermal expansion caused by the temperature difference encountered during the combinatorial processing operations. The epoxy utilized in some embodiments for protrusion 804 is stable up to temperatures of about 3000 degrees F., with limited outgassing. To further limit exposure to the epoxy, a layer of a thin film is deposited over the surface of the substrate carrier. In some embodiments the layer is composed of a dielectric. However, where the combinatorial processing may evaluate metal deposition, the thin film may be composed of a metal.

Any of the operations described herein that form part of the invention are useful machine operations. The invention also relates to a device or an apparatus for performing these operations. The apparatus can be specially constructed for the required purpose, or the apparatus can be a general-purpose computer selectively activated or configured by a computer program stored in the computer. In particular, various general-purpose machines can be used with computer programs written in accordance with the teachings herein, or it may be more convenient to construct a more specialized apparatus to perform the required operations.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

What is claimed is:

1. A substrate carrier, comprising:
a base for supporting a substrate;
a plurality of support tabs affixed to a surface of the base, the plurality of support tabs having a cavity defined within an inner region of each support tab of the plurality of support tabs;
a plurality of protrusions extending from the surface of the base, wherein one of the plurality of protrusions mates with one of the cavities to support one of the plurality of support tabs; and
a film deposited over the surface of the base, surfaces of the plurality of support tabs, and surfaces of the plurality of protrusions.

2. The substrate carrier of claim 1, wherein the base, the plurality of support tabs, and the film are composed of a same material.

3. The substrate carrier of claim 1, wherein each support tab of the plurality of support tabs has a circular outer surface that is concentric with the inner region of each support tab of the plurality of support tabs.

4. The substrate carrier of claim 1, wherein the plurality of protrusions are cylindrical.

5. The substrate carrier of claim 2, wherein the same material is silicon

6. The substrate carrier of claim 1, wherein each protrusion of the plurality of protrusions is composed of an epoxy material.

7. A substrate carrier, comprising:
a base for supporting a plurality of substrates, the base including an alignment notch for aligning the substrate carrier; and
a plurality of support tabs affixed to a surface of the base; wherein multiple support tabs of the plurality of support tabs support a single substrate, and wherein a shape of each substrate of the plurality of substrates is different than a shape of the substrate carrier.

8. The substrate carrier of claim 8 wherein the shape of each substrate is rectangular and the shape of the substrate carrier is circular.

9. The substrate carrier of claim 8 further comprising:
a film deposited over the surface of the base and surfaces of the plurality of support tabs.

10. The substrate carrier of claim 9 wherein the film and the substrate carrier are composed of silicon

11. The substrate carrier of claim 7 further comprising:
a plurality of support protrusions extending from the surface of the base, each support extension supporting one of the plurality of support tabs.

12. The substrate carrier of claim 11, wherein the plurality of support protrusions are composed of an epoxy material.

13. The substrate carrier of claim 12, wherein the plurality of support protrusions are cylindrical.

14. The substrate carrier of claim 12, further comprising:
a film deposited over the surface of the base, surfaces of the plurality of support protrusions, and surfaces of the plurality of support tabs.

15. The substrate carrier of claim 14, wherein the film is silicon dioxide.

16. The substrate carrier of claim 7 wherein a portion of the plurality of support tabs are spring loaded.

17. The substrate carrier of claim 7 wherein the base includes an alignment notch disposed on a periphery of the substrate carrier.

18. The substrate carrier of claim 7 wherein the plurality of support tabs are ring shaped.

19. The substrate carrier of claim 18, wherein a cavity of the ring shaped support tabs mates with a support protrusion extending from the surface of the base.
